(19) United States
(12) Patent Application Publication
(10) Pub. No.: US 2026/0262324 A1
(43) Pub. Date: Sep. 3, 2026

(54) METHOD FOR IMPROVING CONVERSION EFFICIENCY OF A PHOTOVOLTAIC CELL AND ASSOCIATED EQUIPMENT

(71) Applicant: COMMISSARIAT A L'ENERGIE ATOMIQUE ET AUX ENERGIES ALTERNATIVES, PARIS (FR)

(72) Inventors: Jordi VEIRMAN, GRENOBLE CEDEX 09 (FR); Jean-Sébastien CARON, GRENOBLE CEDEX 09 (FR); Pedro JERONIMO, GRENOBLE CEDEX 09 (FR)

(21) Appl. No.: 18/876,044

(22) PCT Filed: Jun. 15, 2023
(86) PCT No.: PCT/EP2023/066148

§ 371 Date: Dec. 17, 2024

(30) Foreign Application Priority Data
Jun. 20, 2022 (FR) 2206001

(51) Int. Cl. H10F 71/00

(52) U.S. Cl. CPC H10F 71/134; H10F 71/128

(57) ABSTRACT

A method for improving conversion efficiency of a photovoltaic cell includes treating the cell by exposing it to electromagnetic radiation having a treatment irradiance; and cooling the cell until its temperature reaches a threshold temperature, the exposure of the cell to electromagnetic radiation being maintained and the cooling irradiance of the electromagnetic radiation being greater than or equal to the treatment irradiance.

### TECHNICAL FIELD OF THE INVENTION

The technical field of the invention is that of improving conversion efficiency of a photovoltaic cell, whether the latter is isolated or in a group in a photovoltaic module (or a photovoltaic string).

This invention relates more particularly to a method for improving conversion efficiency of a photovoltaic cell and associated equipment. It also relates to a method for improving conversion efficiency of a plurality of interconnected photovoltaic cells.

### TECHNOLOGICAL BACKGROUND OF THE INVENTION

High conversion efficiency photovoltaic cells are known to improve their energy conversion efficiency under the combined action of lighting and exposure to high temperatures. These treatments are called “enhancement treatments”. These effects can be of a very diverse nature and can originate in an improvement in the substrate of the photovoltaic cell and/or improvement in the interfaces between the layers making up said photovoltaic cell.

Despite the diversity of the physical mechanisms behind these effects, it is to be noted that recent developments in enhancement treatments now make it possible to contemplate treatments in the order of ten seconds or so, enabling an industrial treatment rate to be achieved. However, the gain in enhancement provided by these short enhancement treatments is generally incomplete, that is, below the maximum gain achievable with longer enhancement treatments.

Within this context, there is a need to improve enhancement gains while maintaining industrial production rate.

One of the reasons for this reduction in enhancement gain is the creation of defects in the substrate and/or layers of a cell when it is maintained at high temperature “in the dark”, that is, without treatment illumination. This is especially the case at the end of the enhancement treatment, when the illumination is stopped but the cell treated remains hot.

Among the solutions provided, it is known to reduce the time required to cool the cell in the absence of illumination. For example, document WO 2020/082131 discloses a method for enhancing a silicon substrate wherein cooling is actively carried out at a speed of between 10° C./s and 20° C./s, while reducing the illumination of the substrate. Cooling is kept until the substrate reaches a temperature lower than 150° C.

However, this solution does not provide the expected results. Indeed, even a short residence time at a high temperature (between 150° C. and 200° C.), without illumination or with illumination that is too low, can have an impact on the gain acquired.

There is therefore a need to efficiently freeze the effect of the enhancement at the end of the method.

### SUMMARY OF THE INVENTION

For this, the invention relates to a method for improving conversion efficiency of a photovoltaic cell, said method comprising the following steps of:
heating the photovoltaic cell so that its temperature reaches a temperature range [Tₘ, T_{M}] referred to as the “treatment temperature range”, said treatment temperature range extending between a minimum treatment temperature Tₘ and a maximum treatment temperature T_{M}, the difference between the maximum treatment temperature T_{M} and the minimum treatment temperature Tₘ being lower than 30° C.;
treating the photovoltaic cell so as to increase its conversion efficiency by exposing it to electromagnetic radiation, the temperature of the photovoltaic cell being maintained within the treatment temperature range [Tₘ, T_{M}], the irradiance of the electromagnetic radiation having a first substantially constant value, referred to as the “treatment irradiance”;
cooling the photovoltaic cell by means of an active cooling device until the temperature of the photovoltaic cell reaches a temperature, referred to as the “threshold temperature”, at which the absence of exposure no longer has any effect on the conversion efficiency of the photovoltaic cell;
   the method being remarkable in that the exposure of the photovoltaic cell to the electromagnetic radiation is maintained until the end of the cooling step and in that the irradiance of the electromagnetic radiation during the cooling step has a second value referred to as the “cooling irradiance” and in that the cooling irradiance is greater than or equal to the treatment irradiance.

By conversion efficiency, it is meant the ratio of the electrical power delivered by the photovoltaic cell subjected to a radiation to the power of said radiation. The radiation is, for example, solar radiation having a certain irradiance.

By irradiance, it is meant the surface density of luminous power. It represents the power of electromagnetic radiation received by a unit surface. The electromagnetic radiation is preferably directed perpendicularly to the surface of the photovoltaic cell.

By irradiance, it is meant incidentally the total irradiance of the radiation. For example, it is the integral of the spectral irradiance of the electromagnetic radiation over a spectral range, extending for example between 300 nm and 1200 nm.

By substantially constant irradiance value, it is meant that the irradiance in question varies by less than 10% as a function of time and advantageously by less than 5% as a function of time.

By increasing or improving conversion efficiency, it is meant increasing the electrical power delivered by the photovoltaic cell for an irradiance received and a given temperature (the irradiance received depends on a spectral irradiance). Increasing or improving conversion efficiency means increasing the output parameters of the photovoltaic cell, such as the open-circuit voltage and/or the short-circuit current of the photovoltaic cell and/or the form factor of the photovoltaic cell.

By effect on conversion efficiency, it is meant that the exposure or non-exposure of the photovoltaic cell to electromagnetic radiation does not influence the conversion efficiency of the photovoltaic cell, either positively or negatively. In other words, stopping the exposure of the photovoltaic cell to electromagnetic radiation does not modify the output parameters of the photovoltaic cell, such as its open-circuit voltage and/or its short-circuit current.

By temperature of the photovoltaic cell, it is meant its mean temperature.

Maintaining exposure to electromagnetic radiation upon cooling, with irradiance at least equal to the treatment irradiance, enables the increase in conversion efficiency, referred to as the “enhancement gain”, provided by treatment of the cell to be kept. Once the photovoltaic cell reaches the threshold temperature, exposure to electromagnetic radiation can be stopped, enabling the enhancement gain to be kept. Indeed, at a temperature lower than the threshold temperature, the enhancement gain is frozen. The active cooling device enables the temperature of the photovoltaic cell to be reduced despite the increased irradiance of the electromagnetic radiation.

Further to the characteristics just discussed in the preceding paragraph, the method for improving conversion efficiency of a photovoltaic cell according to the invention may have one or more complementary characteristics from among the following, considered individually or according to any technically possible combination:
the threshold temperature is strictly lower than the treatment temperature range [Tₘ, T_{M}] and preferably at least 10° C. apart from this range, or even at least 20° C. apart from this range, or even more preferably at least 30° C. apart from this range; in other words, the threshold temperature is strictly lower than the minimum treatment temperature Tₘ and at least 10° C. lower than this minimum treatment temperature Tₘ (that is, the threshold temperature Tₛ verifies Tₛ<Tₘ−10° C.), or even at least 20° C. lower than this minimum treatment temperature Tₘ, or even more preferably at least 30° C. lower than this minimum treatment temperature Tₘ
the treatment temperature range [Tₘ, T_{M}] extends over less than 20° C. or even less than 10° C.; in other words, the difference between the maximum treatment temperature T_{M} and the minimum treatment temperature Tₘ is lower than 20° C. or even lower than 10° C.;
the cooling irradiance is greater than 1 kW/m², preferably greater than 3 kW/m², and even more preferably greater than 5 kW/m²;
the cooling irradiance is strictly greater than the treatment irradiance;
the cooling irradiance is constant;
the electromagnetic radiation has, during the cooling step, at least one component within [300 nm; 1200 nm] and advantageously at least a first component within [300 nm; 550 nm] and at least a second component within
the method comprises a step of estimating the threshold temperature, determined by means of conversion efficiency measurements obtained on at least one photovoltaic cell, referred to as a “control cell”, which has undergone a treatment step, and a cooling step during which exposure to electromagnetic radiation is interrupted when said photovoltaic cell reaches an arbitrary temperature;
the method comprises a step of estimating the threshold temperature, determined by means of conversion efficiency measurements obtained on at least one photovoltaic cell, referred to as a “control cell”, as a function of a cooling speed without illumination;
the total duration of the treatment step and the cooling step is lower than 60 s, or even lower than 15 s;
the active cooling device is based on convection and/or conduction heat transfer;
the active cooling system is based on convection of an airflow;
maintaining the temperature of the photovoltaic cell within the treatment temperature range [Tₘ, T_{M}], for example during the treatment step, is achieved by means of electromagnetic radiation and the active cooling device;
in the absence of the active cooling device during the treatment step, the treatment irradiance is lower than 100 kW/m² and preferably lower than 50 kW/m², preferably within [3 kW/m²; 5 kW/m²] when the photovoltaic cell is a “perovskite-based tandem” type photovoltaic cell, preferably within [7 kW/m²; 10 kW/m²] when the photovoltaic cell is a silicon heterojunction photovoltaic cell, and lower than 100 kW/m², and preferably lower than 50 kW/m², when the photovoltaic cell is a “TOPCon” type photovoltaic cell;
electromagnetic radiation has, during the treatment step, at least one component within [300 nm; 1200 nm] and advantageously at least a first component within [300 nm; 550 nm] and at least a second component within
the heating step is advantageously configured to minimise the following amount:

$$1 - {\int }_{0}^{τ} dt \frac{T ( t ) - {T}_{i}}{{T}_{f} - {T}_{i}}$$

where T_{f} is the final temperature of the photovoltaic cell at the end of the heating step, within the treatment temperature range [Tₘ, T_{M}], Tᵢ is the initial temperature of the photovoltaic cell upon execution of the heating step and t is the duration of the heating step;
when the photovoltaic cell is a perovskite-based tandem type photovoltaic cell, the treatment temperature range [Tₘ, T_{M}] is greater than 100° C. (that is, Tₘ>100° C.) and lower than 200° C. (that is, T_{M}<200° C.) and preferably lower than 150° C. (that is, T_{M}<150° C.);
when the photovoltaic cell is a silicon heterojunction photovoltaic cell, the treatment temperature range is greater than 170° C. (that is, Tₘ>170° C.) and lower than 300° C. (that is, T_{M}<300° C.) and preferably lower than 250° C. (that is, T_{M}<250° C.);
when the photovoltaic cell is a TOPCon type photovoltaic cell, the treatment temperature range is greater than 400° C. (that is, Tₘ>400° C.) and lower than 600° C. (that is, T_{M}<600° C.);
minimising the amount 1−∫dt (T(t)−Tᵢ)/(T_{f}−Tᵢ) comprises minimising the amount (T_{f}−Tᵢ)²/2R where R is the heating speed in ° C./s;
during the heating step, the photovoltaic cell is exposed to electromagnetic radiation, the irradiance of the electromagnetic radiation having a third value, referred to as the “heating irradiance”, advantageously strictly greater than the cooling irradiance and preferably greater than 10 kW/m² advantageously greater than 30 kW/m² and even more advantageously greater than 50 kW/m²;
electromagnetic radiation has, during the heating step, at least one component within [300 nm; 1200 nm] and advantageously a first component within [300 nm; 550 nm] and a second component within [800 nm; 1200 nm];
the temperature of the photovoltaic cell during the heating step is controlled so that it is greater than the treatment temperature range [Tₘ; T_{M}] for less than a limit duration; the limit duration satisfying dₘₐₓ·(T−T_{M})<100° C.·s where dₘₐₓ is the limit duration, T is the temperature of the photovoltaic cell and T_{M} is the maximum treatment temperature.

The invention further relates to equipment for improving conversion efficiency of a photovoltaic cell, comprising at least one light source, an active cooling device and means configured to carry out the method for improving conversion efficiency of a photovoltaic cell according to the invention.

Advantageously, the equipment also comprises a controller for controlling each light source and the cooling device as a function of a predetermined profile.

Advantageously, the radiation source is dimensioned to irradiate the entire photovoltaic module.

Still advantageously, the equipment comprises a support being translationally movable relative to the light source and configured to transport a group of photovoltaic cells simultaneously.

The invention also relates to a method for improving conversion efficiency of a group of interconnected photovoltaic cells, said method comprising the step of improving conversion efficiency of each photovoltaic cell of the group of photovoltaic cells by means of the method for improving conversion efficiency of a photovoltaic cell according to the invention.

Advantageously, the step of improving conversion efficiency of each photovoltaic cell is carried out simultaneously on all the photovoltaic cells in the group of photovoltaic cells.

Advantageously, the group of photovoltaic cells is encapsulated in a transparent matrix.

The invention and its different applications will be better understood upon reading the following description and examining the accompanying figures.

### BRIEF DESCRIPTION OF THE FIGURES

The figures are set forth by way of indicating and in no way limiting purposes of the invention. Unless otherwise specified, a same element appearing in different figures has a unique reference.

FIG. 1 schematically represents an example photovoltaic cell such as being able to be implemented by the invention.

FIG. 2 represents an implementation of a method of the invention, enabling the conversion efficiency of a photovoltaic cell as represented by [FIG. 1] to be improved.

FIG. 3 schematically represents equipment configured to implement the method shown in [FIG. 2].

FIG. 4 represents two example implementations of the heating step of the method shown in [FIG. 2].

FIG. 5 schematically represents an example implementation of another method according to the invention, enabling the conversion efficiency of a group of photovoltaic cells to be improved.

### DETAILED DESCRIPTION

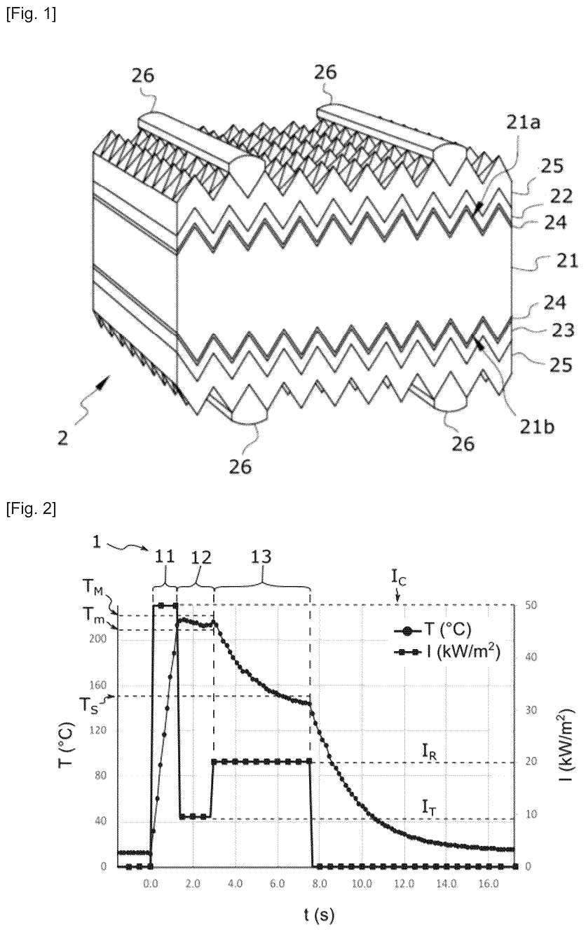

A method 1 for improving conversion efficiency of a photovoltaic cell 2 will now be described. Said method 1 is applicable to different types of photovoltaic cells. It particularly applies to a silicon heterojunction (SHJ) cell 2, as represented in [FIG. 1]. The cell 2 comprises, for example, a doped crystalline silicon substrate 21 and two amorphous silicon layers 22, 23 disposed on either side of the substrate 21. One of the amorphous silicon layers 22, 23 is doped with the same conductivity type as the substrate 21, for example n-type, and the other layer is doped with the opposite conductivity type, that is, p-type.

The heterojunction is formed by the n-doped crystalline silicon substrate 21 and the p-doped amorphous silicon layer, this layer forming the emitter of the cell 2. The emitter can be located on the front or rear face of the cell 2.

The silicon heterojunction cell 2 is particularly sensitive to defects located at the interface between the crystalline silicon substrate 21 and the amorphous silicon layers 22-23. These defects can be dangling bonds or impurities such as metal ions. They introduce energy levels into the band gap of the silicon and increase the number of electron-hole recombinations at the interfaces, which deteriorates the conversion efficiency of the cell, especially the output parameters of the photovoltaic cell, such as the open-circuit voltage.

The cell 2 can also include an intrinsic hydrogenated amorphous silicon passivation layer 24, disposed between the substrate 21 and each amorphous silicon layer 22, 23. It can also be covered with a transparent conductive oxide (TCO) layer 25.

Alternatively, the photovoltaic cell 2 can be a so-called “tandem” perovskite-based photovoltaic cell. It comprises, for example, a silicon heterojunction coupled to a perovskite-based junction.

According to another alternative, the photovoltaic cell 2 can be a so-called “TOPCon” (Tunneling Oxide Passivated Contact) photovoltaic cell. This is especially a silicon heterojunction cell in which the substrate is separated from a doped layer (and especially the emitter) by a tunnel barrier.

FIG. 2 illustrates an example implementation of the method 1 for improving conversion efficiency of a silicon heterojunction cell 2. More particularly, [FIG. 2] illustrates a measurement of the temperature T (plotted on the left-hand ordinate) of the cell 2 in the course of the method 1. By temperature T of the cell 2, it is preferably meant the mean temperature of said cell 2. Actually, this temperature T is, for example, measured at a point in the cell 2 by means of a thermocouple and does not maybe accurately represent the mean temperature of the cell 2. However, to simplify the description of the method 1, it will be hypothesised that the temperature does not vary much within the cell 2 itself.

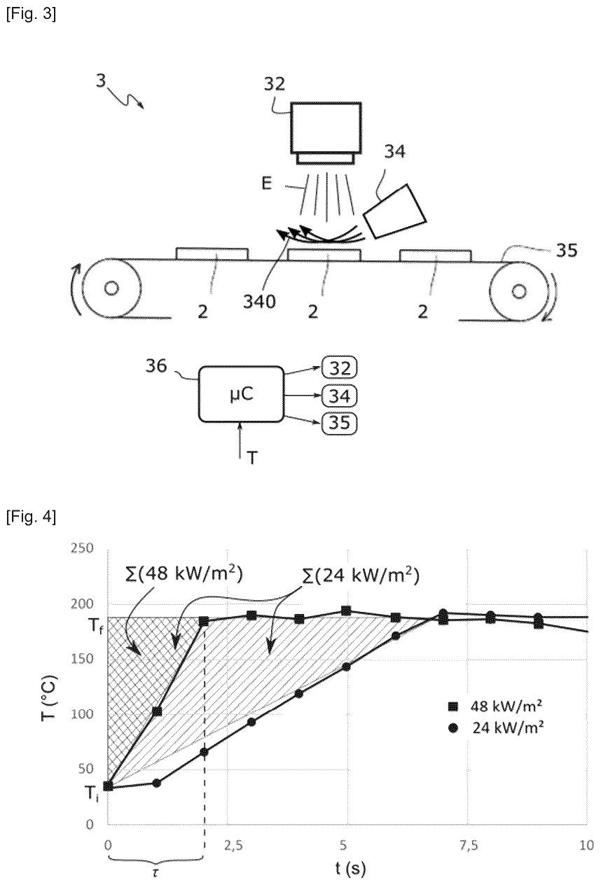

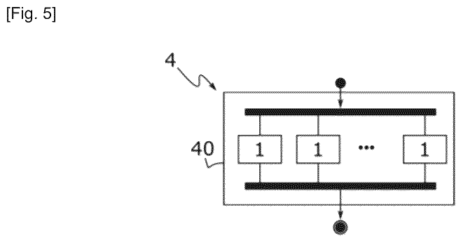

The method 1 is implemented, for example, by means of equipment 3 as illustrated in [FIG. 3]. This may be conventional equipment, such as equipment for interconnecting cells, referred to as a “stringer”. However, said equipment 3 is advantageously configured to be able to carry out the method 1 according to the invention. It comprises, for example, at least one light source 32, an active cooling device 34 and a controller 36. Equipment 3 also comprises a support 35 being translationally movable relative to the light source. This movable support 35 is called “conveyor 35” in the following.

The controller 36 is configured to control the light source 32 and the active cooling device 34 so as to implement the method 1 for improving conversion efficiency of a photovoltaic cell 2 as described hereafter.

More particularly, the controller 36 is configured, for example, to control the aforementioned elements according to a predetermined profile. Said predetermined profile comprises, for example, as a function of time, the irradiance of each light source 32, the cooling power of the active cooling device 34 or the translation speed of the conveyor under each light source 32. A cell 2 can be disposed on the conveyor 35 of equipment 3 in order to be treated. The conveyor 35 is dimensioned to support a group of cells 2, interconnected or not, so that they can be treated simultaneously.

In the initial state (before t=0.0 s), the temperature T measured in the cell 2 is 12° C. In the implementation shown in [FIG. 2], the method 1 initially comprises a step of heating 11 the cell 2 so that its temperature T reaches a temperature range [Tₘ; T_{M}] referred to as the “treatment temperature range” or the “enhancement temperature range”.

The treatment temperature range is particular in that it extends over less than 30° C. It defines a temperature range in which the cell 2 will be maintained during a treatment step. Advantageously, the temperature range extends over less than 20° C., or even over less than 10° C.

Heating 11 is carried out so that the net heat flux from the cell 2 is positive (from the point of view of the cell 2). By net heat flux, it is meant the sum of the heat fluxes leaving the cell 2 and the heat fluxes entering the cell 2. The outgoing heat fluxes comprise, for example, the heat fluxes removed by conductive transfer (with the elements in contact with the cell) and/or convective transfer (for example with the ambient air) and/or by radiative transfer (according to, for example, Stefan-Boltzmann's law). The incoming heat fluxes comprise, for example, heat fluxes supplied by conductive transfer (for example with a hot element in contact with the cell) and/or by radiative transfer (for example by means of electromagnetic radiation E). A positive net heat flux increases the temperature of the cell 2.

Heating 11 of the cell 2 is preferably carried out by exposing the cell 2 to electromagnetic radiation E (radiative heat transfer). It may be completed by means of a heating plate (conductive heat transfer). In this step, the irradiance of the radiation has a value I_{C}, referred to as the heating irradiance. In the current example, the heating irradiance I_{C} is constant and equal to 50 kW/m² (irradiance values plotted on the right-hand ordinate in [FIG. 2]). The objective of the heating step 11 is to increase, quickly if possible, the temperature T of the cell 2 so that it reaches the treatment temperature range [Tₘ; T_{M}]. The heating irradiance I_{C} is then relatively high, so that the rise time of the temperature is short. The heating step 11 ends once the temperature T in the cell 2 reaches the treatment temperature range [Tₘ; T_{M}].

In the example of [FIG. 2], the treatment temperature range extends, in this example, between Tₘ=210° C. and T_{M}=220° C. The temperature T in the cell 2 at the end of the heating step 11 is T=210° C.

The temperature rise during the heating step 11 can be very quick and can lead to a brief overshoot of the treatment temperature range. This overshoot should preferably be limited as it can have a strong impact on the thermal budget of the cell 2. The overshoot is therefore preferably low, or even absent. The presence of an overshoot may be acceptable if it enables a short heating step 11, thus reducing the total duration of the treatment. For this, a criterion can be used to determine whether the cell temperature during the heating step 11 is controlled. This criterion indicates that the temperature of the cell 2 should not exceed the maximum treatment temperature for more than a limit duration. Beyond this limit duration, it may be considered that the heating step 11 is not sufficiently controlled and has too great an impact on the thermal budget of the cell 2. The stronger the temperature overshoot relative to the maximum treatment temperature T_{M}, the shorter this limit duration should be. The limit duration d is advantageously described by

$$d \cdot ( T - {T}_{M} ) < 100 ° C . \cdot s$$

where T_{M} is the upper bound of the treatment temperature range.

Thus, an overshoot of 50° C., during which the temperature of the cell 2 reaches 270° C. for a treatment temperature range extending over [210° C.; 220° C.], should preferably last less than two seconds. An overshoot at 320° C. considering the same treatment temperature range (that is, an overshoot of 100° C.) should preferably last less than one second. Advantageously, the limit duration d is preferably described by

$$d \cdot ( T - {T}_{M} ) < 50 ° C . \cdot s$$

In this case, an overshoot of 50° C. should preferably last less than one second and an overshoot of 100° C. should preferably last less than 0.5 s. It should be noted that the limit duration is advantageously considered over the entire heating step 11. It therefore corresponds to the sum of the durations of several overshoots.

In all cases, the temperature of the cell 2 should preferably not exceed a critical temperature beyond which the cell undergoes quick irreversible damage. The critical temperature of a silicon heterojunction cell is, for example, 300° C. The critical temperature of a tandem cell is, for example, 200° C. (tandem cells are not normally able to withstand an overshoot). The critical temperature of a TOPCon cell is, for example, 600° C.

In order to avoid any overshoot, the heating step 11 may end for a short instant before the temperature T in the cell 2 reaches the treatment temperature range [Tₘ; T_{M}]. However, it ends early, nevertheless taking account of the thermal inertia of the cell 2 (and advantageously also the thermal inertia of the environment of the cell 2) and the irradiance of the radiation E during the next step (treatment step). In this way, the temperature T of the cell 2 reaches the treatment temperature range, minimising the chance of noticing an overshoot.

The electromagnetic radiation E implemented during the heating step 11 is emitted by the light source 32. The cell 2 is advantageously oriented so that it presents one of its faces to the light source 31 and preferably so that the electromagnetic radiation E is perpendicular to this face.

The method 1 consecutively comprises a step 12 for treating the cell 2. Treatment 12 of the cell 2 is carried out by exposing the latter to electromagnetic radiation E. However, the latter has an irradiance I_{T}, referred to as the “treatment irradiance” or “enhancement irradiance”, which is preferably lower than the heating irradiance I_{C}. Electromagnetic radiation E used in this step advantageously comes from the same light source 32 as that used during the heating step. It may, however, come from another light source. Treatment irradiance I_{T} is selected to increase the conversion efficiency of the cell 2. In the example given, treatment irradiance I_{T} is substantially constant and equal to 9.5 kW/m.²

Silicon heterojunction cells 2 are known to improve their energy conversion efficiency by about 0.3% absolute under the combined action of lighting and temperature. This so-called “enhancement” phenomenon results, for example, from the improvement of at least one of the hydrogenated amorphous silicon passivation layers 24 and/or from the improvement of the interfaces between the amorphous silicon layers 22, 23 and the TCO layers 25. The enhancement may also improve the TCO layer 25 itself.

The same principle applies to other types of cell, such as a tandem cell or a TOPCon cell. On the other hand, the treatment temperature range may be different.

Treatment irradiance I_{T} is also selected so that the temperature of the cell 2 is maintained in the temperature range [Tₘ; T_{M}] during this step. For example, the treatment temperature range for a silicon heterojunction cell is advantageously greater than 170° C. It is advantageously lower than 300° C. when the treatment time is short (for example much lower than 15 s). Apart from a short treatment duration, the temperature range is preferably lower than 250° C.

The treatment temperature range for a tandem cell is advantageously greater than 100° C. and advantageously lower than 160° C. For a TOPCon cell, it is advantageously greater than 400° C. and advantageously lower than 600° C.

In these extended temperature ranges, the treatment temperature range considered is advantageously reduced and lower than or equal to 30° C. (or even less). In this way, the temperature of the cell 2 is more or less constant and the method 1 is carried out in a controlled and reproducible manner.

For the temperature of the cell 2 to be maintained in the temperature range [Tₘ; T_{M}], the treatment irradiance I_{T} is selected, for example, so that the net heat flux from the cell 2 is low or zero for the duration of the treatment step 12. The incoming heat flux depends at least on the heat supplied by the electromagnetic radiation E of irradiance I_{T}.

Zero net heat flux enables the thermal equilibrium of the cell 2 to be kept for the duration of the treatment. It can be difficult to achieve perfect equilibrium (that is, a perfectly zero heat flux). The net heat flux is therefore advantageously low enough for the temperature of the cell 2 to remain in the treatment range [Tₘ; T_{M}] for the duration of the treatment step 12.

It is also advantageous to actively cool the cell 2 during the treatment step 12 in order to increase the heat flux leaving the cell 2. In this way, the treatment irradiance I_{T} can be increased to compensate for the outgoing heat flux. Higher treatment irradiance I_{T} especially makes it possible to increase the treatment kinetics and also to further increase the energy conversion efficiency. Active cooling of the cell 2 during the treatment step 12 can be carried out by means of the active cooling device 34.

The method 1 then comprises a step of cooling 13 the cell 2. Cooling 13 of the cell 2 is carried out in such a way as to freeze the increase in the conversion efficiency of the cell 2 obtained during the treatment step 12. It is carried out especially until the temperature of the cell 2 is lower than or equal to a temperature T_{S}, referred to as the “threshold temperature”. At a temperature lower than the threshold temperature T_{S}, the absence of exposure to electromagnetic radiation no longer has any effect on the conversion efficiency of the cell 2. In this example of a silicon heterojunction cell, the threshold temperature T_{S} is equal to 150° C. (that is, 60° C. apart from the treatment range).

During the cooling step 13, exposure of the cell to the electromagnetic radiation E is maintained. The electromagnetic radiation E therefore has an irradiance I_{R}, during this step, referred to as the “cooling irradiance”.

At the start of the cooling step 13 (when the irradiance rises from 9.5 kW/m² to 20 kW/m²) a thermal inertia may be noticeable, during which the cell 2 keeps a substantially constant temperature T within the treatment temperature range. The noticeable thermal inertia may comprise the thermal inertia specific to the cell 2 and/or a thermal inertia of the cooling device 34 (which may have a non-negligible start-up time). The end of the treatment step 12 and the start of the cooling step 13 then advantageously coincide with the instant when the control instructions are sent to the different instruments (such as the light source 32 or the cooling device 34). Actually, the start-up inertia of the light source 32 is generally zero and the gross change in irradiance can then represent the change of step.

Radiation E can be emitted by a different light source as long as the cooling irradiance satisfies the aforementioned conditions (irradiance and orientation especially). However, it is more advantageous for radiation E to come from the same source as that used upon treatment 12. Indeed, it is preferable that the exposure to said radiation E is maintained, without a drop in exposure (which can be noticed when switching from one source to another) at the risk of noticing a reduction in conversion efficiency.

Cooling irradiance I_{R} is selected so that it does not compensate for the heat flux leaving the cell 2 during the cooling step. The net heat flux is therefore negative (from the point of view of the cell 2, in other words, the outgoing heat fluxes exceed the incoming heat fluxes). Thus, even in the presence of electromagnetic radiation E, the temperature in the cell 2 decreases. Cooling 13 (that is, negative net heat flux) is made possible, for example, by implementing the active cooling device 34 which, despite the heat supplied by the cooling irradiance I_{R}, enables the temperature of the cell 2 to be lowered to the threshold temperature T_{S}. The active cooling device 34 can implement conduction and/or convection heat transfer. In the first case, it may be a temperature-controlled chuck. In the second case, it may be a blower configured to create an airflow 340 sweeping across one face of the cell 2 (preferably the face exposed to radiation E). The flow rate of the airflow is then adjusted (by means of the controller 36, for example) to remove the heat required for cooling.

Another way of defining the end of the treatment step 12 and the start of the cooling step 13 is to observe the change in sign of the net heat flux. The start of the cooling step 13 corresponds to the instant when the net heat flux becomes negative.

Counter-intuitively, the cooling irradiance I_{R} is greater than or equal to the treatment irradiance I_{T}. In the example of [FIG. 2], the cooling irradiance I_{R} is constant and strictly greater than the treatment irradiance I_{T} and equal to 20 kW/m². According to one implementation, the cooling irradiance I_{R} could have a non-constant irradiance, for example increasing or decreasing, while still being greater than or equal to the treatment irradiance I_{T}.

When the temperature of the cell 2 reaches the threshold temperature T_{S}, the exposure of the cell 2 to the electromagnetic radiation E is advantageously interrupted. The cooling device 34 can then also be interrupted. However, it is preferable for the active cooling device 34 to continue operating until the temperature of the cell 2 reaches a temperature much lower than the threshold temperature T_{S}, for example room temperature.

In the example illustrated in [FIG. 2], maintaining the exposure of the cell 2 to the electromagnetic radiation E during the cooling step 13 makes it possible to keep an enhancement action of the cell 2 until the temperature T of the cell 2 is sufficiently low to freeze the arrangement of the layers and of the interfaces between these layers. The threshold temperature T_{S} thus corresponds to a temperature at which the arrangement of these layers and/or interfaces no longer changes as a function of time. Exposure to electromagnetic radiation E can therefore be stopped without any risk of degrading these structures and therefore without any risk of degrading conversion efficiency.

However, the threshold temperature T_{S} varies as a function of the type of cell. For example, the threshold temperature T_{S} for a tandem cell is lower than or equal to 70° C. In the case of a TOPCon cell, the threshold temperature T_{S} is lower than or equal to 400° C. In the case of a silicon heterojunction cell (as shown in [FIG. 2]), the threshold temperature T_{S} is lower than or equal to 160° C.

In the example of [FIG. 2], the duration of the method (heating 11, treatment 12 and cooling 13 steps) is 7.5 s. The method therefore makes it possible to improve conversion efficiency of the cell 2 and to freeze said improvement in a time much lower than 60 s or even lower than 15 s. The improvement method as such is therefore compatible with an industrial production rate (a duration lower than 60 s being an upper limit and a duration of between 15 s and 20 s being a frequent upper limit).

Although the method 1 enables a cell 2 to be quickly enhanced, the cooling speed is not a restriction of the method 1. Indeed, methods of prior art provide solutions for quickly cooling the cell to be enhanced, thus minimising the loss of gain. Conversely, the method 1 according to the invention provides the continuation of the heat treatment of the cell 2 until the temperature of the cell 2 freezes its state (and therefore the improvement in conversion efficiency). The cooling step 13 can therefore be carried out slowly, as long as it keeps the exposure of the cell 2 to electromagnetic radiation when its temperature is greater than its threshold temperature T_{S}. Slow cooling may be necessary when the thermal stresses in the cell 2 during quick cooling are too great. This is the case, for example, for a cell in a photovoltaic module or photovoltaic string.

For the cooling irradiance I_{R} to have a sufficient impact on the conversion efficiency, it is advantageously selected to be greater than 1 kW/m². The higher the cooling irradiance I_{R}, the better the conversion efficiency is kept (or even improved) upon cooling. Cooling irradiance I_{R} is therefore preferably greater than 3 kW/m² and even more preferably greater than 5 kW/m.²

The active cooling device 34 is dimensioned as a function of the cooling irradiance I_{R} so that the net heat flux for cell 2 is outgoing. The active cooling device is all the more important as the cooling irradiance _{IR} is high, as the difference between the treatment temperature range and the threshold temperature is high and as the targeted cooling time is short.

However, by virtue of the active cooling device 34, the cooling irradiance I_{R} can be selected to be strictly greater than the treatment irradiance I_{T} without this having a negative impact on the cell 2 (since its temperature decreases and gets further away from the critical temperatures at which it can be damaged). In this way, the cooling irradiance I_{R} can be high, enabling the increase in conversion efficiency to be kept or even further improved.

[Table 1] illustrates an example improvement (called “gain” in the table) in conversion efficiency obtained with five silicon heterojunction cells, after implementation of the method 1 according to the invention and after implementation of a method of prior art. The treatment temperature range considered extends between Tₘ=210° C. and T_{M}=220° C. The threshold temperature considered is T_{S}=160° C. The treatment irradiance I_{T} is 9.5 kW/m². The heating irradiance I_{C} is 50 kW/m². According to the two methods, the cells are heated for 1.5 s and then treated for 1 s. The two methods differ in that the method according to the invention comprises a cooling step 13 as described previously (cooling irradiance of 20 kW/m² until the cell temperature reaches 160° C. after approximately 5 s) and in that the method according to prior art comprises a cooling step without illumination and at a cooling speed of 10° C./s (that is, quick cooling in the dark as suggested by document WO 2020/082131). Each method is implemented on a group of five silicon heterojunction cells. Each group of five cells shows an almost identical initial conversion efficiency (to within less than 0.1%). The first group, which has undergone the method according to prior art, has a gain in its conversion efficiency lower than 0.3% absolute. On the other hand, the second group, which has undergone the method according to the invention, has a gain in its conversion efficiency greater than 0.4% absolute.

TABLE 1

| | Method according | Method according |
|---|---|---|
| | to prior art | to the invention |
| Initial conversion | 21.891 | 21.899 |
| efficiency | | |
| (% absolute) | | |
| Final conversion | 22.158 | 22.302 |
| efficiency | | |
| (% absolute) | | |
| Gain (% absolute) | 0.267 | 0.404 |

During the cooling step 13, the electromagnetic radiation E can have at least one component within [300 nm; 1200 nm]. Indeed, this spectral window provides the best enhancement efficiency. Below 300 nm, the radiation E is too energetic and can damage the cell 2. In addition, absorption is mainly carried out at the surface and therefore does not allow effective treatment within the thickness of the cell 2. Above 1200 nm, absorption of electromagnetic radiation E is low and considerably prolongs the minimum cooling time. It is therefore advantageous for the electromagnetic radiation E to comprise at least one component between [300 nm; 1200 nm], or even to extend substantially over this spectral range.

Even more advantageously, electromagnetic radiation E comprises at least two components. At least a first component in the range [300 m; 550 nm], referred to as the “blue” range, and at least a second component in the range [800 nm; 1200 nm], referred to as the “infrared” or IR range. Combining these two ranges makes it possible to benefit from the advantages of each range. Each component in the blue range is absorbed efficiently at the surface and therefore efficiently improves conversion efficiency (especially by improving the stacking of layers at the surface of the cell 2). Each component in the IR range is absorbed over the entire thickness of the cell 2 and makes it possible to homogenise the improvement in efficiency in the cell 2.

In the example of [FIG. 2], electromagnetic radiation E used comprises a first component at 455 nm and a second component at 940 nm. Irradiance of the second component represents 70% of the total irradiance of the electromagnetic radiation. Irradiance of the first component represents 30% of this total irradiance.

The threshold temperature T_{S} plays an important role in the correct implementation of method 1. Indeed, incorrect evaluation of this temperature can lead to premature stop of electromagnetic radiation E and therefore a reduction in the improvement in conversion efficiency. For this, the method 1 can advantageously comprise a preliminary step of estimating the threshold temperature T_{S} of the cell 2. By estimating, it is meant that the threshold temperature T_{S} is not measured directly on the cell 2 but determined by means of measurements obtained on cells having equivalent characteristics.

One way to do this may be to carry out a measurement of the conversion efficiency of a plurality of cells, referred to as “control cells”, having properties close to those of the cell 2 to be improved (which will be called the “cell to be enhanced”). The properties that can influence the threshold temperature T_{S} of a cell are generally the state of the layers making up said cell as well as the state of the interfaces between these layers. It is therefore advisable for the control cells to be obtained using the same method as that used to obtain the cell 2 to be enhanced. For example, the methods for depositing or growing the different layers are carried out under the same conditions and using the same materials.

Each control cell of the plurality of control cells undergoes a treatment method similar to the heating 11, treatment 12 and cooling 13 steps as described previously. However, the treatment method differs from the method according to the invention in that exposure to the electromagnetic radiation is stopped arbitrarily, upon cooling, for different temperatures, referred to as stop temperatures. The conversion efficiency of each control cell is then determined, for example, by measuring the open-circuit voltage of each control cell. The conversion efficiencies obtained before and after the treatment are compared as a function of the stop temperatures. A first part of the control cells may show a substantially equal (for example, to within 20%) and maximum improvement in conversion efficiency. On the other hand, another part of the control cells may show a smaller, or even zero, or even negative improvement in efficiency. The control cells whose exposure to electromagnetic radiation has been stopped while their temperatures were still greater than the threshold temperature T_{S} (which is to be determined) are those showing the least gains in conversion efficiency. The control cells whose exposure to electromagnetic radiation has been stopped when their temperatures were lower than the threshold temperature T_{S} (which is to be determined) are those showing the best gains in conversion efficiency. A stop temperature associated with a high efficiency gain can be considered as the threshold temperature T_{S} estimated for enhancing the cell 2. The threshold temperature T_{S} can also be estimated by interpolation between the conversion efficiency gains measured and the associated stop temperatures.

According to another method, each control cell of the plurality of control cells undergoes exposure to high irradiance, for example 10 kW/m², for about one minute, while maintaining the temperature of each cell at 200° C. When the exposure to radiation is switched off, the control cells are stored at different constant temperatures, for example of between 100° C. and 300° C. This can be carried out, for example, by depositing the cells onto supports heated to the desired temperatures for at least 30 s. Measuring the conversion efficiency of each cell makes it possible to determine the cell or cells for which the efficiency gain is acceptable, as well as the desired storage temperatures. The threshold temperature is then the lowest storage temperature.

The active cooling device 34 can also be implemented during the treatment step 12 (as long as the net heat flux is low or even zero). Said device 34 thus contributes to regulating the temperature of the cell 2 upon exposure to electromagnetic radiation E. In this way, the temperature T of the cell 2 can be maintained more robustly within the treatment temperature range. The interest of this is to be able to use a higher treatment irradiance I_{T} than would be the case in the absence of thermal regulation, enabling improvement of conversion efficiency to be accelerated or increased.

In the absence of the active cooling device 34 during the treatment step 12, treatment irradiance I_{T} is advantageously selected so that the temperature T in the cell 2 remains within the treatment temperature range [Tₘ; T_{M}]. Treatment irradiance I_{T} is advantageously lower than 100 KW/m² and even more advantageously lower than 50 kW/m². Treatment irradiance I_{T} can highly depend on the type of cell 2 to be enhanced.

For example, when the latter is a silicon heterojunction photovoltaic cell, as shown in [FIG. 2], then treatment irradiance I_{T} is preferably within [7 kW/m²; 10 kW/m²]. Indeed, a silicon heterojunction cell 2 should preferably keep a temperature lower than 300° C. or even lower than 250° C.

According to another example, when the cell 2 is a tandem photovoltaic cell, treatment irradiance I_{T} is preferably within [3 kW/m²; 5 kW/m²].

The treatment temperature range for a TOPCon cell should be lower than 600° C. Treatment irradiance I_{T} can therefore, in this case, be lower than 100 kW/m² and, for example, around 50 kW/m².

Electromagnetic radiation E may also have, during the treatment step 12, at least one component in the range [300 nm; 1200 nm] and advantageously at least one component in the blue range and at least one component in the IR range. This may also be the case during the heating step 11.

In order to reduce the total duration of the method 1, it is advantageous for the heating step to be carried out quickly. It is therefore advantageous to heat the cell 2 quickly so that its temperature T quickly reaches the treatment temperature range.

FIG. 4 illustrates, for example, a measurement of the temperature T of a silicon heterojunction cell 2 as a function of time t, during two executions of the heating step 11. The two executions differ from each other by the heating irradiance I_{C} used. In the first case (squares in [FIG. 4]), the heating irradiance I_{C} is 48 kW/m². In a second case (circles in [FIG. 4]), the heating irradiance I_{C} is halved to 24 kW/m².

In the first case, the temperature rise of the cell 2 to a final temperature T_{f} of 180° C. is carried out in τ=2 s. It is advantageous for the heating step 11 to end at the end of this duration t. In the second case, the temperature rise of the cell 2 to the final temperature T_{f} of 180° C. is achieved in 7 s.

Reducing the duration of the heating step 11 is equivalent to minimising the area between the ordinate on [FIG. 4] and the temperature curve T. In other words, reducing the duration amounts to minimising the following amount

$$1 - {\int }_{0}^{τ} dt \frac{T ( t ) - {T}_{i}}{{T}_{f} - {T}_{i}}$$

where T_{f} is the final temperature of the cell 2 at the end of the heating step 11, Tᵢ is the initial temperature of the cell 2 and τ is the duration of the heating step 11 (in [FIG. 4], τ is illustrated for an associated irradiance equal to 48 kW/m²). Minimising this amount approximately amounts to minimising the area of the triangle formed by the ordinate of [FIG. 4] and the rising front of the temperature curve. In other words, the amount to be minimised can be approximated by

$$\sum = \frac{{( {T}_{f} - {T}_{i} )}^{2}}{2 R}$$

where R is the heating speed in ° C./s. The area of the triangle associated with the first heating (I_{C}=48 kW/m²) is double hatched. The area of the triangle associated with the second heating (I_{C}=24 kW/m²) is equal to the area of the double-hatched triangle and the area of the single-hatched triangle. In order to reduce the duration of the heating step 11, heating irradiance I_{C} is then advantageously greater than 10 KW/m². Heating irradiance I_{C} greater than 30 kW/m² makes it possible to carry out the temperature rise of a silicon heterojunction cell in less than 4 s. Heating irradiance I_{C} greater than 50 kW/m² makes it possible to carry out the temperature rise of a same cell in less than 2 s.

Advantageously, heating irradiance I_{C} is substantially constant in order to supply the maximum amount of energy in the minimum amount of time.

The invention also relates to a method 4 for improving conversion efficiency of a group of cells 2. The group is particular in that the cells 2 are interconnected two by two. For example, they are cells 2 within a photovoltaic string or within a photovoltaic module. In the latter case, the cells 2 may be encapsulated in a transparent matrix, intended to protect the cells from the external environment (such as air or humidity) and/or disposed between two protective plates, for example made of glass, intended to ensure the mechanical strength of the assembly. The group of cells 2 can also comprise a backsheet.

The transparent matrix and/or protective plates can increase the thermal inertia of the cells 2, as they can also contribute to the thermal insulation of the latter. This may result in a reduction in conversion efficiency when these cells are treated according to a method of prior art. Indeed, the cells are likely to remain at a high temperature for longer without being exposed to electromagnetic radiation (or not sufficiently exposed) at the end of illumination.

The method 4 provides a solution to this problem in that it comprises a step 40 of improving conversion efficiency of each cell 1 in the group of cells. For this, the improvement step comprises carrying out the method 1 for improving conversion efficiency of a cell 2 as previously described on each cell 2 in the group of cells. By virtue of the active cooling device 34, exposure to electromagnetic radiation can be maintained until the cells 2 reach the threshold temperature T_{S}. This implementation echoes the slow cooling discussed previously.

Advantageously, the improvement method 1 is applied simultaneously to all the cells 2 in the group. In this way, even if cooling is slow (for example because of the thermal inertia caused by the transparent matrix and/or the protective plates and/or the backsheet), the number of cells treated in parallel makes the method 4 compatible with an industrial production rate.

The equipment 3 illustrated in [FIG. 3] can advantageously be configured to carry out the improvement method on the group of cells 2. It is sufficient, for example, that the entire group can be placed under the light source 32 and the blower 34.

1. A method for improving conversion efficiency of a photovoltaic cell, said method comprising:
heating the photovoltaic cell so that its a temperature thereof reaches a treatment temperature range [Tₘ, T_{M}], said treatment temperature range extending between a minimum treatment temperature Tₘ and a maximum treatment temperature T_{M}, a difference between the maximum treatment temperature T_{M} and the minimum treatment temperature Tₘ being lower than 30° C.;
treating the photovoltaic cell so as to increase a conversion efficiency thereof by exposing the photovoltaic cell to electromagnetic radiation, the temperature of the photovoltaic cell being maintained within the treatment temperature range [Tₘ, T_{M}], a treatment irradiance of the electromagnetic radiation having a first substantially constant value;
cooling the photovoltaic cell with an active cooling device until the temperature of the photovoltaic cell reaches a threshold temperature, at which an absence of exposure to the electromagnetic radiation no longer has any effect on the conversion efficiency of the photovoltaic cell;
wherein the exposure of the photovoltaic cell to the electromagnetic radiation is maintained until the end of the cooling step and wherein the irradiance of the electromagnetic radiation during the cooling step has a second value forming a cooling irradiance and wherein the cooling irradiance is greater than or equal to the treatment irradiance.

2. The method according to claim 1, wherein the threshold temperature is strictly lower than the minimum treatment temperature Tₘ.

3. The method according to claim 1, wherein the cooling irradiance is strictly greater than the treatment irradiance.

4. The method according to claim 1, wherein the electromagnetic radiation has, during the cooling step, at least one first component within [300 nm; 550 nm] and at least one second component within [800 nm; 1200 nm].

5. The method according to claim 1, wherein a total duration of the method is less than 60 S.

6. The method according to claim 1, wherein the active cooling device is based on convection and/or conduction heat transfer.

7. The method according to claim 1, wherein maintaining the temperature of the photovoltaic cell within the treatment temperature range [Tₘ, T_{M}] is achieved with electromagnetic radiation and the active cooling device.

8. The method according to claim 1, wherein, in the absence of the active cooling device during the treatment step, the treatment irradiance is lower than 100 kW/m².

9. The method according to claim 1, wherein, during the heating step, the photovoltaic cell is exposed to electromagnetic radiation, the irradiance of the electromagnetic radiation having a third value forming a heating irradiance, strictly greater than the cooling irradiance.

10. An equipment for improving conversion efficiency of a photovoltaic cell, comprising at least one light source, an active cooling device and means configured to carry out the method for improving conversion efficiency of a photovoltaic cell according to claim 1.

11. The equipment according to claim 10, further comprising a controller for controlling each light source and the cooling device as a function of a predetermined profile.

12. A method for improving conversion efficiency of a group of interconnected photovoltaic cells, said method comprising improving the conversion efficiency of each photovoltaic cell of the group of photovoltaic cells by means of with the method for improving conversion efficiency of a photovoltaic cell according to claim 1.

13. The method according to claim 12, wherein improving conversion efficiency of each photovoltaic cell of the group of photovoltaic cells is carried out simultaneously on all the photovoltaic cells of the group of photovoltaic cells.

14. The method according to claim 13, wherein the group of photovoltaic cells is encapsulated in a transparent matrix and/or disposed between two protective plates.
